(19) United States
(12) Patent Application Publication
(10) Pub. No.: US 2017/0126074 A1
(43) Pub. Date: May 4, 2017

(54) EFFICIENCY ESTIMATION IN A SWITCHING POWER CONVERTER

(71) Applicant: MediaTek Inc., Hsin-Chu (TW)

(72) Inventor: Vladimir A. Muratov, Manchester, NH (US)

(73) Assignee: MediaTek Inc., Hsin-Chu (TW)

(21) Appl. No.: 15/150,807

(22) Filed: May 10, 2016

Related U.S. Application Data
(60) Provisional application No. 62/247,280, filed on Oct. 28, 2015.

(51) Int. Cl. H02J 50/80; H02M 1/08; G01R 19/00; H02M 3/158

(52) U.S. Cl. CPC H02J 50/80; H02M 3/158; H02M 1/08; G01R 19/0046; H02M 2001/0009

(57) ABSTRACT

Methods and apparatus for indirectly determining an input current or an output current of a DC/DC switching converter operating in a closed loop. A controller of the switching converter determines an efficiency of the switching converter based, at least in part, on an input voltage of the switching converter, an output voltage of the switching converter, and at least one switching timing parameter for controlling electronic switches in the switching converter. The input current or output current is indirectly determined based, at least in part, on the efficiency of the switching converter and a direct measurement of the input current or the output current, whichever one is not being indirectly determined, using a current sensor.

### CROSS REFERENCE TO RELATED APPLICATIONS

This application claims priority to U.S. Provisional Application Ser. No. 62/247,280, titled “Efficiency Estimator for use in Switching Converters and Associated Methods,” filed Oct. 28, 2015, which is hereby incorporated by reference in its entirety.

### BACKGROUND

DC/DC converters are devices configured to convert a source of direct current (DC) from one voltage level to another, and are often used in portable electronic devices such as smartphones and laptop computers to convert (e.g., 12V) battery power to various electronic circuits within the device that have different voltage requirements. DC/DC converters have many different topologies, examples of which include step-down (also referred to as “buck”) converters, which supply an output voltage lower than the input voltage, and step-up (also referred to as “boost”) converters, which supply an output voltage higher than the input voltage. Switched mode DC/DC converters convert an input voltage level to another voltage level by temporarily storing input energy in a storage component (e.g., inductors, capacitors) and releasing the energy to the output at a different voltage.

A simplified schematic of a buck switching converter is illustrated in FIG. 1. The buck converter includes a controller 100 (e.g., a microcontroller) configured to control operation of the switches 102, 104. During operation, when switch 102 is closed and switch 104 is open, energy is stored in inductor 110 of a filter circuit that includes inductor 110 and capacitor 112. When switch 102 is open and switch 104 is closed, the energy stored in the inductor is discharged to provide a voltage Vₒᵤₜ across the load 120. By adjusting the duty cycle (the ratio of the high-side switch on time to the switching period) of the charging voltage, the amount of power transferred to the load 120 may be controlled.

To maintain a desired voltage Vₒᵤₜ, a feedback path 130 is provided, which measures the voltage across the load and provides this voltage measurement to controller 100, which can adjust the duty cycle of the charging voltage, as necessary, to achieve the desired output voltage.

### SUMMARY

Some embodiments relate to a DC/DC switching converter. The DC/DC switching converter comprises a first circuit configured to measure an output voltage across a load coupled between output terminals of the switching converter, and a controller. The controller is configured to receive as feedback, the output voltage measurement from the first circuit, adjust, based on the feedback, a duration of on/off states of electronic switches in the switching converter to supply a desired output voltage across the output terminals, and determine based, at least in part, on an efficiency of the switching converter, an indirect current measurement of an input current or an output current of the switching converter.

Some embodiments relate to a method of indirectly determining an input current or an output current of a DC/DC switching converter operating in a closed loop. The method comprises determining, by a controller, an efficiency of the switching converter based, at least in part, on an input voltage of the switching converter, an output voltage of the switching converter, and at least one switching timing parameter for controlling electronic switches in the switching converter, directly measuring the input current or the output current of the switching converter using a current sensor, and indirectly determining by the controller the input current or the output current, whichever is not directly determined by the current sensor, wherein the indirectly determining is based, at least in part, on the efficiency of the switching converter and the directly determined input current or output current.

Some embodiments relate to a wireless power receiver for a wireless charging system. The wireless power receiver comprises a DC/DC switching converter configured to indirectly determine an input current or an output current of the switching converter based, at least in part, on an efficiency of the switching converter.

The foregoing summary is provided by way of illustration and is not intended to be limiting.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 shows a schematic of a buck switching converter;

FIG. 2 shows a schematic of a buck switching converter in which sources of losses in the circuitry are illustrated;

FIG. 3 illustrates a timing diagram representing switching timing parameters of a switching converter used to determine an efficiency of the converter in accordance with some embodiments;

FIG. 4A shows a block diagram of components for calculating an efficiency of a switching converter in accordance with some embodiments;

FIGS. 4B-4D show timing diagrams for calculating an efficiency of a switching converter in accordance with some embodiments;

FIG. 5 shows a flow chart of a process for indirectly determining an input current or an output current of a DC/DC switching converter in accordance with some embodiments;

FIG. 6 shows a power chain of a wireless power system in which a switching converter designed in accordance with some embodiments may be used;

FIG. 7 shows a schematic of a wireless power receiver in accordance with some embodiments; and

FIG. 8 illustrates a plot of desired output characteristics of a power converter in accordance with some embodiments.

### DETAILED DESCRIPTION

In some switching converters, it is desirable to have information about input and output currents and voltages. Some conventional techniques for measuring input/output currents involve adding additional circuitry (e.g., a current sensor) at the location in the circuit where the current is to be measured. The inventor has recognized and appreciated that existing techniques and circuitry for measuring input/output currents in a switching converter that rely on direct measurement of the current using a current sensor may be improved by using techniques that indirectly measure the current based on an estimation of the efficiency of the switching converter. When the current to be measured is large (e.g., the output current of a buck converter or the input current of boost converter), the value of the resistance element(s) needed for the current sensor is large, leading to power losses in the switching converter circuitry. Unlike directly measuring current, which is sometimes technically difficult to implement and/or requires additional circuitry, the techniques described herein indirectly determine an input/output current based on an estimation of the efficiency of the switching converter. As described in more detail below, some embodiments measure a limited number of parameters to indirectly determine the desired current value without requiring additional current sensor circuitry, resulting in less power consumption.

For switching converters operating in continuous mode, the theoretical relationship between input and output currents is determined by the duty factor D at which the switches are operating. The terms “duty factor” and “duty ratio” are used interchangeably herein. The theoretical duty factor is a function of the ratio between the converter output voltage and its input voltage. The input and output currents are also related with a ratio that is determined by the duty factor. The inventor has recognized that indirectly estimating the current based on the theoretical duty factor is not possible in practice due to losses introduced into the switching converter circuitry when non-ideal circuit components are used. The inventor also has recognized that the practical (actual) duty factor compensates for the losses incurred by the non-ideal circuit components through the use of feedback control. Based on these observations, the inventor has appreciated that comparing the actual duty ratio to the theoretical duty ratio allows for an accurate estimation of the efficiency of the switching converter. With this information, in addition to other measurement(s), the actual input/output current of the converter can be determined irrespective of the losses in the system. In accordance with some embodiments, the input/output current of a switching converter is determined, at least in part, on a measurement of the input voltage, the output voltage, and one or more switching timing parameters (e.g., the actual duty ratio set by the controller of the switching converter).

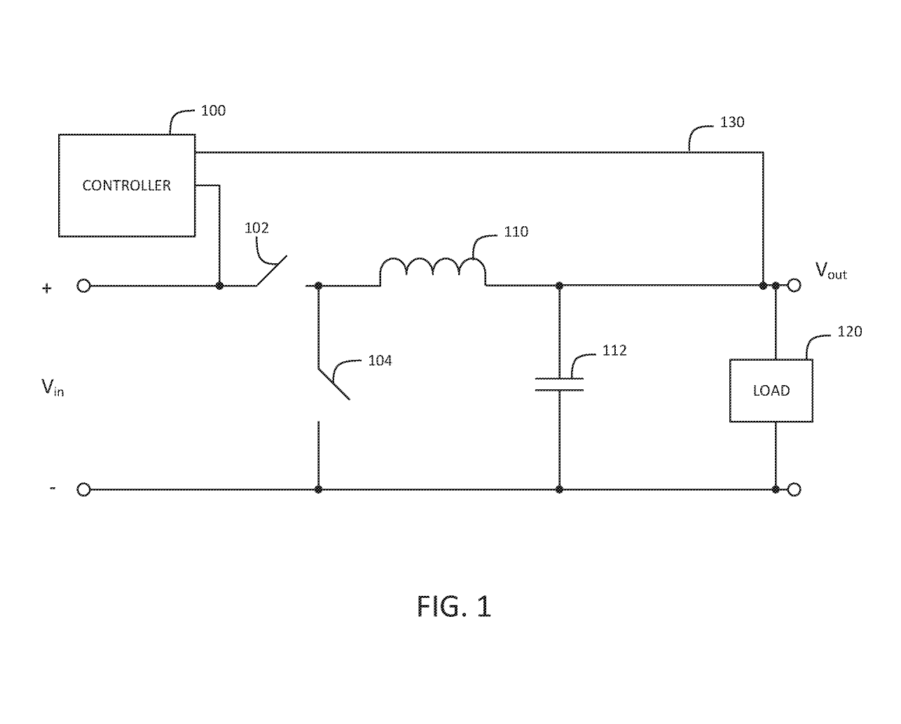

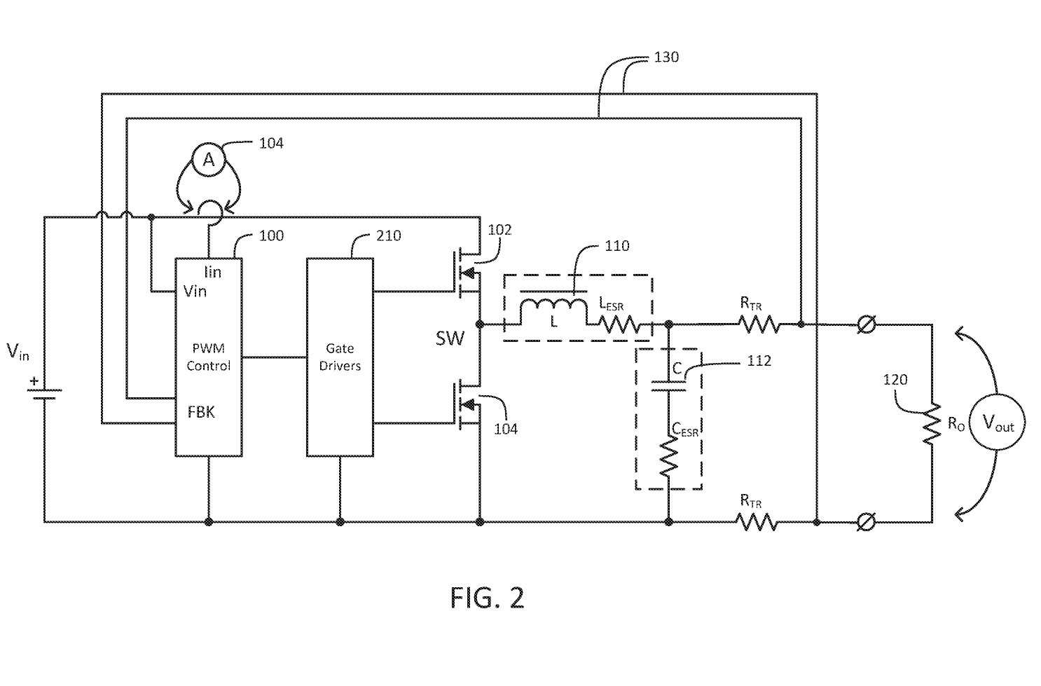

FIG. 2 illustrates a more detailed schematic implementation of the generalized buck converter shown in FIG. 1. As shown, switches 102, 104 are implemented in the buck converter of FIG. 2 as a pair of MOSFETS. However, it should be appreciated that other types of electronic switches may alternatively be used. Controller 100 is implemented as a microprocessor control unit (MCU) configured to provide pulse width modulation (PWM) control of the MOSFETS 102, 104 such that a duty factor for the switching provides an amount of voltage charging in the switching converter that provides a desired output voltage, as discussed above. Controller 100 may be configured to control the switching timing of the electronic switches in the switching converter using techniques other than PWM, and embodiments are not limited in this respect.

Controller 100 outputs signals to gate drivers 210, which in turn supply voltages to the gates of MOSFETS 102 and 104 to turn the switches on or off at particular timings to achieve the desired duty factor. Load 120 is represented by resistor R_{O}, and feedback path 130, which provides the output voltage Vₒᵤₜ to the controller 100 is implemented as a pair of traces to measure the voltage across the load 120 at the output terminals of the switching converter. A current sensor A 104 is also shown, and is configured to directly measure the input current Iᵢₙ of the buck converter and to provide the value of the input current to the controller 100.

Resistance elements added to the buck converter of FIG. 2 illustrate some sources of losses in the switching converter. In addition to switching losses due to the switching of MOSFETS 102, 104, other sources of loss in the switching converter include equivalent series resistances (ESR) of inductor 110 (L_{ESR}) and capacitor 112 (C_{ESR}). Trace resistances (R_{TR}) are also shown as loss sources. Each of these sources of loss reduces the efficiency of the switching converter. The switching converter adjusts the duty factor of the switching converter to compensate for the efficiency losses based on the output voltage signal fed back to the controller 100 using feedback path 130. For example, if the desired output voltage for a buck converter is 5V and the input voltage of the converter is 10V, the theoretical duty factor needed to achieve the output voltage is 50%. However, when the switching converter circuitry is implemented using non-ideal components that have losses, examples of which are illustrated in FIG. 2, the duty factor deviates from the theoretical value to compensate for the losses. Continuing with the example above, to produce the desired output voltage of 5V, the controller will increase the duty factor above 50% (e.g., 55%) to compensate for the losses in the circuitry. The particular amount that the duty factor will deviate from the theoretical value is determined, at least in part, by the measured output voltage of the converter, as discussed above.

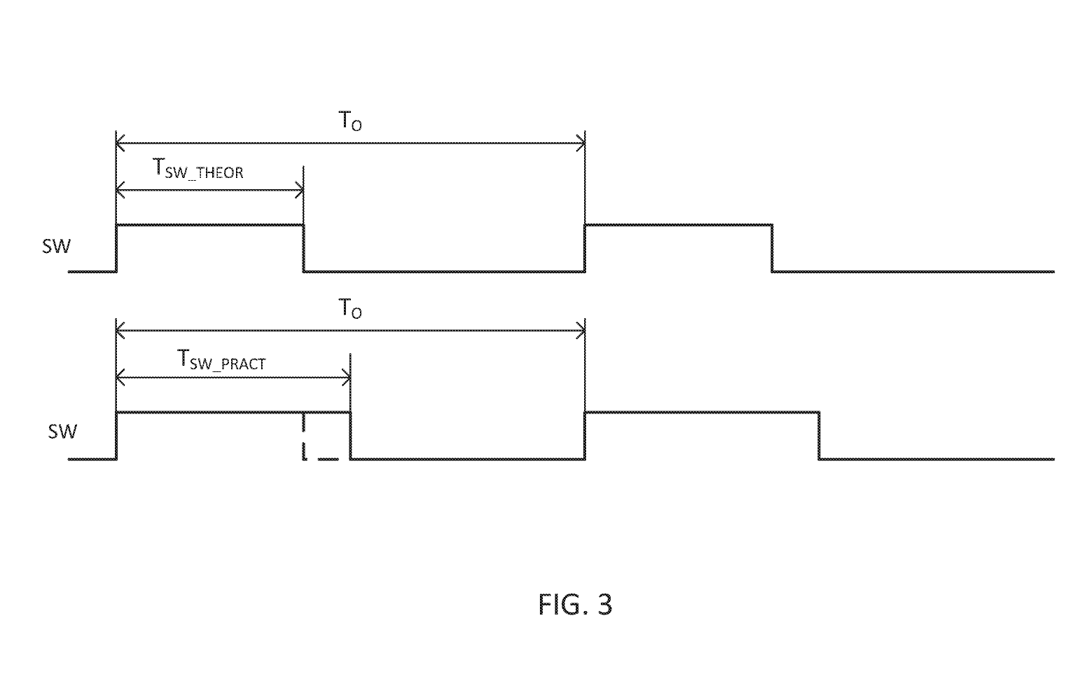

FIG. 3 shows a timing diagram illustrating how the controller of a switching converter may modify the duty factor of the switches in the switching converter to compensate for losses in the switching converter circuitry. The inventor has recognized and appreciated that in a buck converter, efficiency (η) of the converter may be expressed as a ratio between the theoretical duty factor and the practical (actual) duty factor as follows:

$$η = \frac{{D}_{THEOR}}{{D}_{PRACT}} .$$

The theoretical duty factor (D_{THEOR}) is determined as follows:

$${D}_{THEOR} = \frac{{T}_{SW \_ THEOR}}{{T}_{O}} = \frac{{V}_{OUT}}{{V}_{IN}} ,$$

where T_{SW}_{_}_{THEO R} is the switching on time and Tₒ is the switching period. The practical duty factor is determined as follows:

$${D}_{PRACT} = \frac{{T}_{SW \_ PRACT}}{{T}_{O}} = \frac{{T}_{SW \_ THEOR}}{{T}_{O} \cdot η} = \frac{{D}_{THEOR}}{η} = \frac{{V}_{OUT}}{{V}_{IN} \cdot η} .$$

Solving for the efficiency η gives the following relation:

$$η = \frac{{V}_{OUT}}{{V}_{IN}} \frac{1}{{D}_{PRACT}} = \frac{{V}_{OUT}}{{V}_{IN}} \frac{{T}_{O}}{{T}_{SW \_ PRACT}} .$$

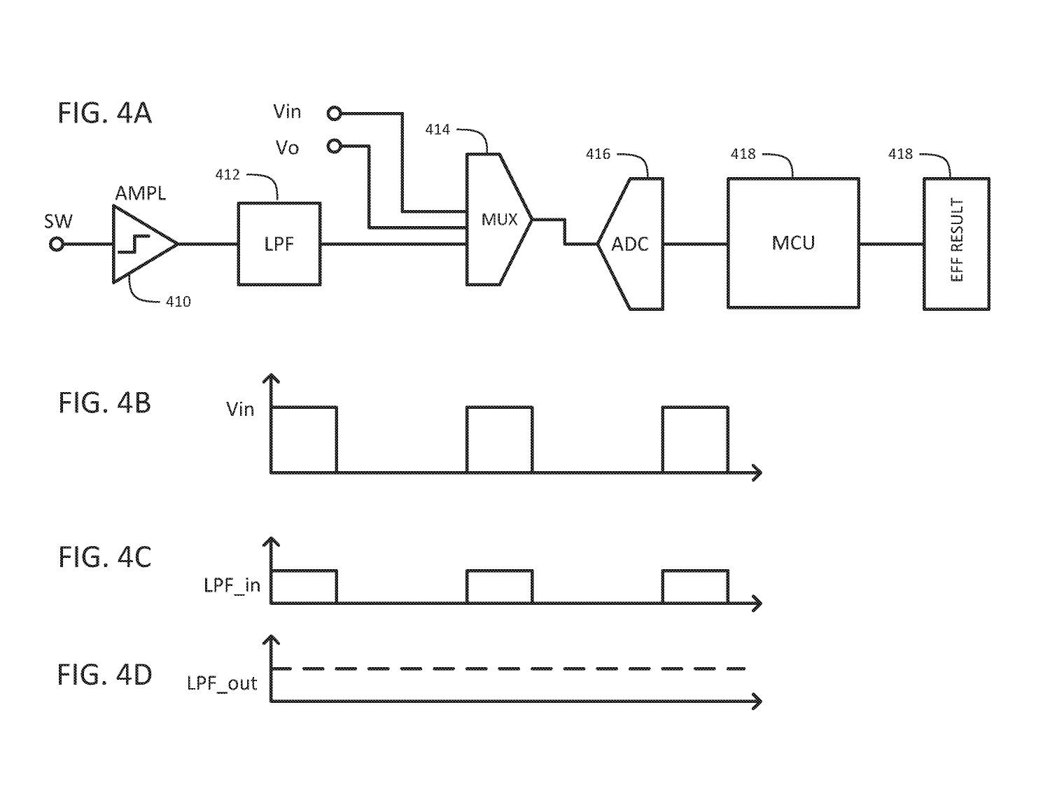

Accordingly, the buck converter efficiency may be determined as a result of an algebraic operation of the measured output voltage (V_{OUT}), the measured input voltage (V_{IN}), the duration of the switching on state (T_{SW}_{_}_{PRACT}), and the switching period (T_{O}). In some embodiments, the algebraic operation may be performed by the controller of the switching converter, as discussed in more detail below in connection with FIG. 4.

The input and output currents of a buck converter are related by the duty factor as follows: I_{IN}=I_{OUT}·D_{PRACT}. Solving for the output current I_{OUT} and substituting the above relation for D_{PRACT} gives the following relation:

$${I}_{OUT} = \frac{{I}_{IN}}{{D}_{PRACT}} = \frac{{V}_{IN} \cdot {I}_{IN}}{{V}_{OUT}} η .$$

Accordingly, the output current I_{OUT} of a buck converter may be determined as an algebraic expression of the measured input current (I_{IN}), the measured input voltage (V_{IN}), the measured output voltage (V_{OUT}), and the estimated efficiency (η) of the buck converter.

The example above describes indirectly determining the output current of a buck converter based on measured values for the input and output voltages, the input current, and the estimated efficiency of the buck converter as a technique for replacing a current sensor that directly measures the output current. It should be appreciated, however, that the techniques for estimating the efficiency of a switching converter may be used with any type of DC/DC switching converter operated in continuous mode in a closed feedback loop and having any topology including, but not limited to, a buck converter, a boost converter, a buck-boost converter, and a SEPIC converter.

Depending on the particular topology used, the estimation of the switching converter efficiency may be different. For example, the efficiency for a boost converter may be determined as follows:

$$η = \frac{{V}_{OUT} - {V}_{IN}}{{V}_{OUT} } \frac{{T}_{SW \_ PRACT}}{{T}_{O}} ,$$

and the input current may be indirectly measured in accordance with the following relation:

$${I}_{IN} = {I}_{OUT} \cdot {D}_{PRACT} = \frac{{V}_{OUT} \cdot {I}_{OUT}}{{V}_{IN} \cdot η} .$$

FIG. 4A shows a block diagram of an efficiency estimation process in accordance with some embodiments. As discussed above, the efficiency of a switching converter may be estimated in accordance with some embodiments based on a measurement of the input voltage, the output voltage, and one or more switching timing parameters such as the switching on time and the switching period. As shown in the example buck converter in FIG. 2, the controller 100 may directly measure the input voltage (V_{IN}) and the output voltage (V_{OUT}) may be provided to the controller via feedback path 130. An example of the measured input voltage is shown in FIG. 4B. In the block diagram of FIG. 4A, the input and output voltages are provided as input to multiplexer 414. One or more switching timing parameters are also provided as input to multiplexer 414, as discussed in more detail below.

In some embodiments, information about the switching pulse dynamics is determined and provided as input to an amplitude normalizing circuit 410. For example, the input to the amplitude normalizing circuit may be a voltage at the switching node of the switching converter circuit or one of the gate drive coupled voltages that control the MOSFET switches to turn on/off. The function of the amplitude normalizing circuit 410 is to normalize the analog voltage pulse waveform based on a reference voltage such that when the voltage in the analog voltage pulse waveform is equal to the reference voltage, the duty factor is assumed to be 100%.

The output of the amplitude normalizing circuit 410 is a pulse waveform as illustrated in FIG. 4C. To convert the timing information into a voltage, the normalized pulse output from the amplitude normalizing circuit is passed through a low pass filter 412 to provide a low ripple DC voltage as shown in FIG. 4D. The magnitude of the voltage at the output of the low pass filter 412 is proportional to the switching on time of the switching converter. To transfer the time waveform into a voltage, in some embodiments the low pass filter 412 may be implemented using a calibrated current source and a calibrated capacitor. Charge is stored in the calibrated capacitor for a particular amount of time when the input voltage waveform is high. The voltage across the capacitor when the capacitor stops charging (i.e., when the input voltage is low) is proportional to the switching on time. Accordingly, the switching on time is converted into a voltage at the output of the low pass filter 412, which is then input to the multiplexer 414.

The multiplexer 414 feeds each of the input voltage, the output voltage, and the low pass filter voltage to an analog-to-digital converter (ADC) 416, which digitizes the signals and provides the digital signals to the microcontroller 418. The microcontroller, having the information necessary to estimate the efficiency for a particular topology of switching converter processes the digital information to determine a digital code for the efficiency estimate 418.

As discussed above, the efficiency estimate, once determined, may be used in combination with a directly measured input/output current to indirectly determine a desired current (e.g., the output current of a buck converter or an input current of a boost converter) of the switching converter. For example, the output current of a buck converter may be determined as

$${I}_{OUT} = \frac{{V}_{IN} \cdot {I}_{IN}}{{V}_{OUT}} η ,$$

where η is the efficiency of the buck converter estimated using the technique described above in connection with FIG. 4A.

It should be appreciated that the techniques described in connection with FIG. 4 for measuring the duty ratio of the switching converter and providing this information to the microcontroller 418 is just one way in which the duty ratio may be measured, and other techniques are possible. For example, in some embodiments, the controller may know what the current duty cycle of the switching converter is without having to separately measure it using the techniques described in FIG. 4 or using some other suitable technique.

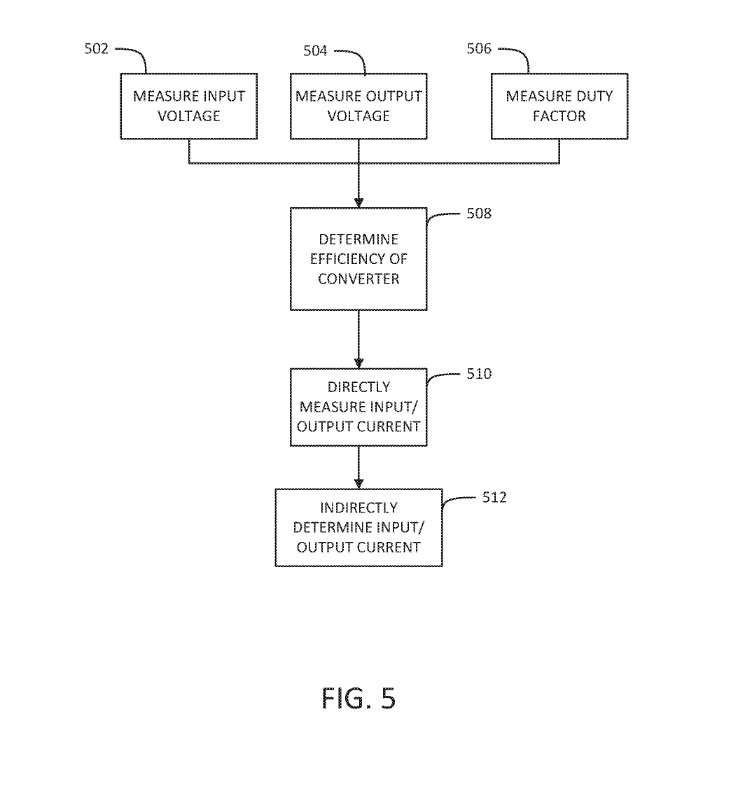

FIG. 5 shows a process for indirectly determining an input/output current for a switching converter in accordance with some embodiments. In act 502, the voltage at the input of the switching converter is measured. In act 504, the voltage at the output of the switching converter is measured. As discussed above, switching converters that operate in a closed loop measure the output voltage provided across a load at the output of the switching converter and provide the output voltage as feedback to the switching converter controller to enable the controller to adjust the duty factor of the switching to compensate for losses in the switching converter circuitry. Accordingly, in such switching converters, a measurement of the output voltage separate from the feedback is not required as the controller is already provided with this information. In act 506, the duty ratio of the switching of the electronic switches in the switching converter is measured. It should be appreciated that any suitable switching timing parameter or parameters may be determined in act 506, and the duty ratio is only one of such measures. For example, any one or more of the switching on time, the switching off time, and the switching period may be determined in act 506. Acts 502, 504, and 506 are shown in FIG. 5 as occurring in parallel. However it should be appreciated that the measurements in acts 502, 504, 506 may be performed in any order, and embodiments are not limited in this respect.

After the input voltage, output voltage and switching timing parameter(s) have been measured, the process proceeds to act 508, where the measured quantities are used to determine the efficiency of the converter using one or more or relations, examples of which are discussed above for buck and boost switching converter topologies. The process then proceeds to act 510, where a current sensor is used to directly measure the input or output current of the switching converter, whichever one is not being indirectly determined based on the techniques described herein. The inventor has appreciated that the power losses incurred when using a current sensor to directly measure the input/output current of a switching converter are largest when the value of the current to be measured is large. Accordingly, the techniques described herein are particularly advantageous for indirectly measuring the current where its value is expected to be high. For buck converters, the output current is substantially larger than in the input current, whereas for boost converters, the input current is substantially larger than the output current. For this reason, some embodiments are directed to indirectly measuring the output current of a buck converter or indirectly measuring the input current of a boost converter. The direct measurement of the input/output current in act 510 may be performed at any suitable time (e.g., before, after, or during determination of the efficiency of the converter in act 508), and embodiments are not limited in this respect.

After determining the efficiency of the converter in act 508 and directly measuring the input/output current in act 510, the process proceeds to act 512, where the input/output current that was not directly measured is determined based, at least in part, on the determined efficiency and directly measured input/output current.

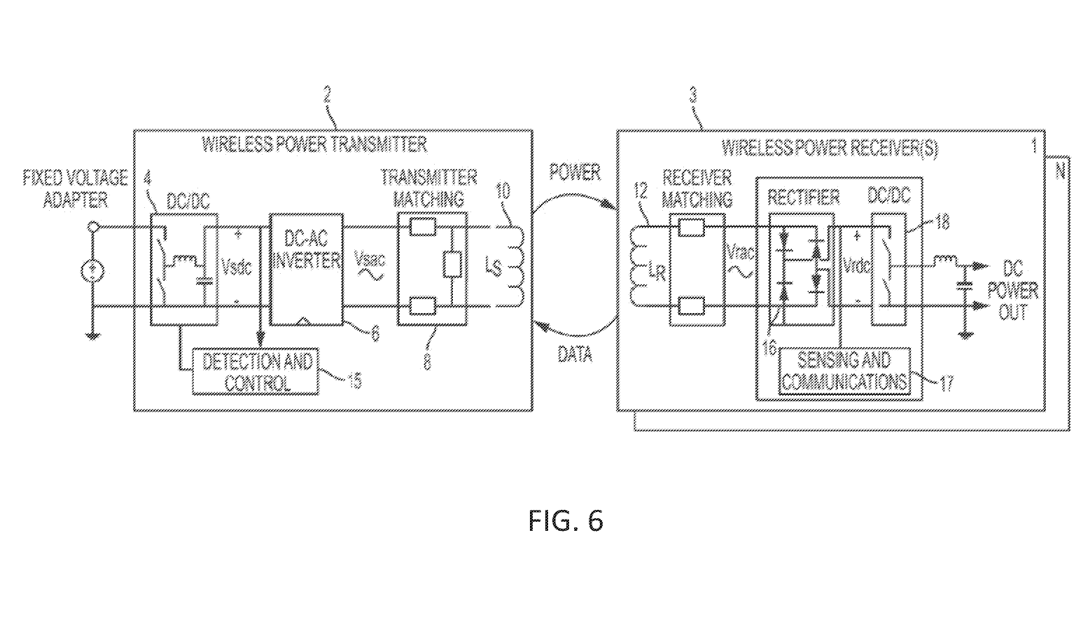

A DC/DC switching converter with efficiency estimation in accordance with some embodiments may be used in combination with any suitable type of circuitry for which lower power consumption is desired. One such application is in the transmit and/or receive circuitry of a wireless power system, an example of which is illustrated in FIG. 6. The wireless power system includes a wireless power transmitter 2 and a wireless power receiver 3. The wireless power transmitter 2 receives a fixed voltage from a DC adapter. The fixed adapter voltage is scaled by a DC/DC converter 4 and applied to an inverter 6. The inverter, in conjunction with the transmitter matching network 8, generates an AC current in the transmit coil 10. The AC current in the transmit coil 10 generates an oscillating magnetic field in accordance with Ampere's law. The oscillating magnetic field induces an AC voltage into a tuned receiver coil 12 of a wireless power receiver 3 in accordance with Faraday's law. The AC voltage induced in the receiver coil 12 is applied to a rectifier 16 that generates an unregulated DC voltage. The unregulated DC voltage is regulated using a DC/DC converter 18, which is filtered and provided to a load, such as a battery of an electronic device.

The wireless power transmitter 2 uses a closed loop power control scheme. The power control scheme allows individual device power needs to be met while providing high efficiency and safe receiver operation. The sensing and communications circuit 17 of the wireless power receiver senses the power demands of the load by measuring the voltage and/or current at the input of the DC/DC converter 18. Instantaneous receiver power is fed back to the wireless power transmitter 2 using a communication channel, shown as the arrow labeled “Data” in FIG. 6. Any suitable communication channel may be used, and may be in accordance with wireless communication standards such as Bluetooth or Near Field Communication (NFC), or by modulating the receiver coil 12, by way of example and not limitation. The sensing and communications circuit 17 sends data regarding the power demands of the receiver to the wireless power transmitter 2. A detection and control circuit 15 of the wireless power transmitter 2 detects the signal from the wireless power receiver 3 and adjusts the output voltage of the DC/DC converter 4 in order to satisfy the power requirements of the wireless power receiver 3.

In accordance with some embodiments, one or both of the DC/DC converter 4 in the wireless power transmitter 2 and the DC/DC converter 18 in the wireless power transmitter 3 may be designed in accordance with the techniques described herein for indirectly determining an input/output current of the converter using an estimation of the efficiency of the converter. By not requiring additional circuitry to measure the input/output current, the power losses in the circuitry are reduced, yielding a system with improved efficiency.

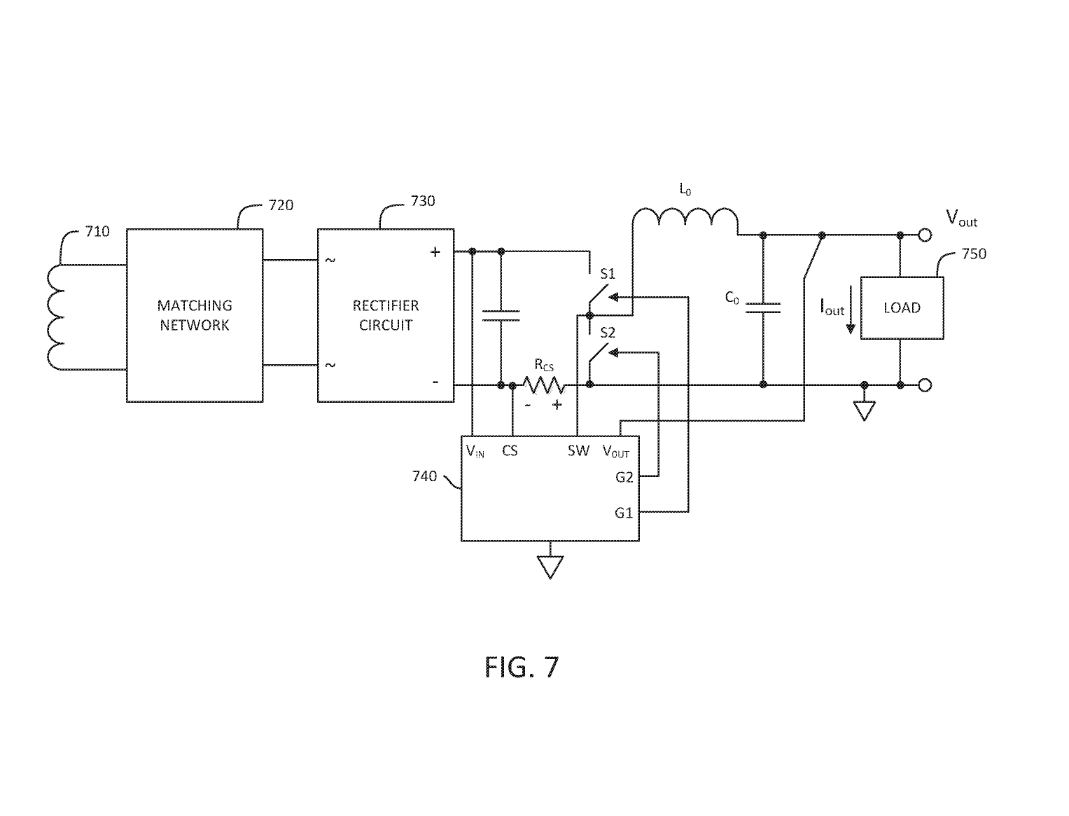

FIG. 7 shows a schematic for a wireless power receiver in accordance with some embodiments. As discussed above in connection with FIG. 6, an oscillating magnetic field generated, for example, by a wireless power transmitter coil, induces an AC voltage into a tuned receiver coil 710 of a wireless power receiver in accordance with Faraday's law. The AC voltage induced in the receiver coil is provided to a matching network 720, which in turn provides an AC voltage to a rectifier circuit 730, examples of which include a diode bridge. Rectifier circuit 730 outputs an unregulated DC voltage. The unregulated DC voltage is regulated using a DC/DC converter, components of which are shown in FIG. 7. The DC/DC converter shown in FIG. 7 has a buck converter configuration, in which the output voltage Vₒᵤₜ is lower than the input voltage V. It should be appreciated, however, that a wireless power receiver configured to use the techniques described herein may include a DC/DC converter having any suitable architecture and components, and embodiments are not limited in this respect.

The DC/DC converter of the wireless power receiver in FIG. 7 is coupled to a microprocessor 740, which is arranged to receive direct measurements of circuit parameters within the DC/DC converter and to provide control signals G1 and G2 to control the switching frequency of switches S1 and S2, respectively, in the converter. For example, microprocessor 740 is arranged to receive direct measurements of the input voltage Vᵢₙ, the output voltage Vₒᵤₜ, the input current Iᵢₙ using current sensor CS (e.g., shown as current sensor A in FIG. 2), and a switching node signal SW measured at the switching node between switches S1 and S2. The output of the switching circuit is filtered by inductor L₀ and capacitor C₀ to produce an output current Iₒᵤₜ to load 750. The microprocessor 740 is configured to estimate the efficiency of the converter based, at least in part, on the direct measurements using one or more of the techniques described herein, and to adjust the control signals G1 and G2 for controlling the switching parameters of switches S1 and S2 as needed to obtain a desired characteristic for the output current Iₒᵤₜ provided to the load 750.

To enhance the user experience with charging mobile devices (e.g., smartphones) from power sources with different available power characteristics, battery charging controllers often employ an adaptive technique based on a falling load line where the battery charging current is proportional to the voltage applied to the charging controller input. For higher applied voltages, the battery charging controller provides more current to charge the battery. For lower applied voltages, less current is provided to charge the battery. This adaptive technique enables the battery charging rate to be adapted to the characteristics of the power source without interruption.

The characteristics of the output load line are determined based on a signal that is proportional to the output current of the DC/DC converter. However, as discussed above, such a signal describing the output current may not be readily available in wireless power receivers that include a switching DC/DC converter between the rectifier of the wireless power receiver and the load. Rather than measure the output current directly, some embodiments derive the output current of the DC/DC converter based on the current measured at the input of the DC/DC converter and an estimate of the DC/DC converter efficiency determined using one or more of the techniques described herein. The output current of the DC/DC converter determined in this way may then be used to determine the characteristics of the load line.

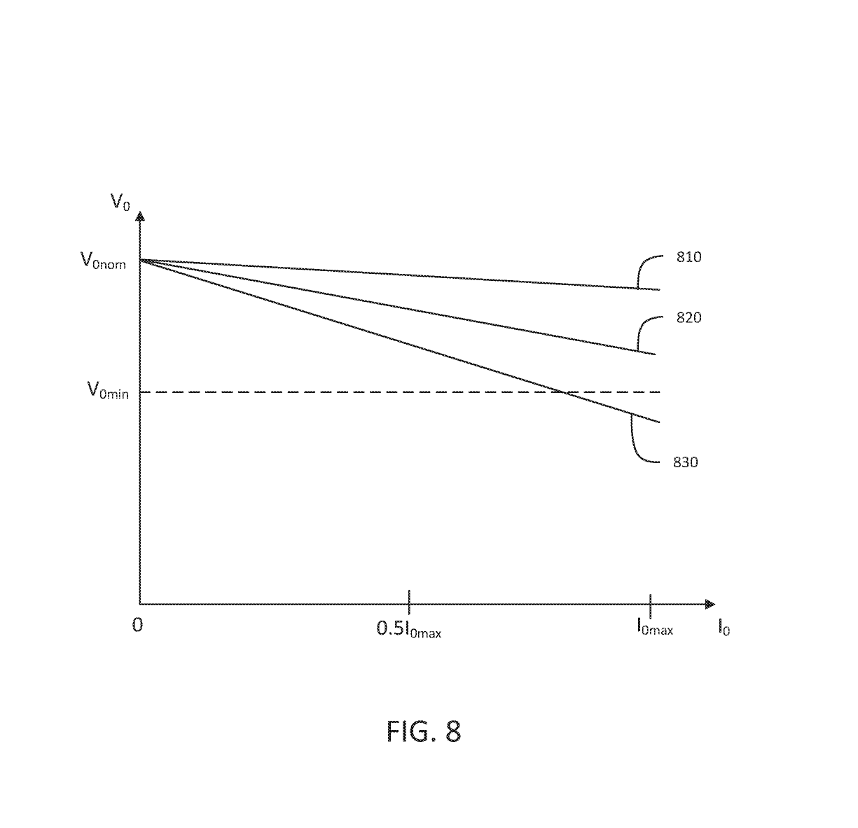

FIG. 8 illustrates three load lines 810, 820, and 830 describing output characteristics for controlling the output impedance of a DC/DC switching converter for a load 750. In particular, the load lines show how the voltage V₀ output from the DC/DC converter changes as a function of the output current I₀ provided to a load 750 to perform a function (e.g., charging a battery). As an example, a battery for a smartphone may be charged at a nominal voltage V₀ₙₒₘ=5V. The battery however, may still charge (albeit at a slower rate) when the output voltage V₀ is lower than the nominal voltage down to a minimum voltage V₀ₘᵢₙ, below which the battery will not charge.

Load line 810 illustrates a load line when there is no I₀ information provided as feedback. The output impedance determined as

$${R}_{SO} = \frac{Δ {V}_{0}}{Δ {I}_{0}}$$

is low due to the high gain in V₀ of the feedback loop of the DC/DC converter. The output load line may be implemented in the DC/DC converter to obtain a controllable output impedance

$${R}_{SO} = \frac{Δ {V}_{O}}{Δ {I}_{O}} = {G}_{CS} {R}_{CS} ,$$

where G_{CS} is the amplification gain of the signal developed on the current sense resistor R_{CS} in the converter of FIG. 7. Load line 820 illustrates when V₀=V₀ₙₒₘ−I₀□R_{SO1}, and load line 830 illustrates when V₀=V₀ₙₒₘ−I₀□R_{SO2}, where R_{SO2}>R_{SO1}. In accordance with some embodiments, the amplification gain (e.g., G_{CS1} and G_{CS2}) in the DC/DC converter may be adjusted to provide a desired output characteristic, examples of which are shown in FIG. 8.

In some embodiments, the output impedance of the DC/DC switching converter may be changed based, at least in part, on the efficiency of the DC/DC switching converter. Changing the output impedance of the DC/DC switching converter comprises determining whether the efficiency of the DC/DC switching converter is lower than a predetermined value and regulating the output impedance when it is determined that the efficiency of the DC/DC switching converter is lower than the predetermined value.

In some embodiments, the output impedance of the DC/DC switching converter may be changed based, at least in part, on at least one control signal received via in-band or out-of-band communication. In some embodiments, the output impedance of the DC/DC switching converter may be changed based, at least in part, on an environmental input of the wireless power receiver. In the load lines shown in FIG. 8, the current path gain G_{CS} may be proportional to the system temperature (e.g., the temperature inside of the wireless power receiver), with higher temperatures corresponding to steeper load lines. For example, load line 810 illustrates a scenario in which the system temperature is low, and load line 830 illustrates a scenario in which the system temperature is high. Wireless power system operation factors other than system temperature may also be taken into consideration to program output load lines determined in accordance with the techniques described herein.

While it may be advantageous to use a DC/DC converter configured in accordance with the techniques described herein in a wireless power system, other applications are also possible. For example, other applications include use in envelope tracking amplifiers, monolithic charger integrated circuits, circuits that require output current protection and circuits that require special output characteristics that depend on the output current of a switching converter.

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A DC/DC switching converter comprising:
a first circuit configured to measure an output voltage across a load coupled between output terminals of the switching converter; and
a controller configured to:
receive as feedback, the output voltage measurement from the first circuit;
adjust, based on the feedback, a duration of on/off states of electronic switches in the switching converter to produce a desired output voltage across the output terminals; and
determine based, at least in part, on an efficiency of the switching converter, an indirect current measurement of an input current or an output current of the switching converter.

2. The DC/DC switching converter of claim 1, further comprising:
a second circuit configured to measure an input voltage of the switching converter; and
wherein the controller is further configured to determine the efficiency of the switching converter based, at least in part, on the input voltage, the output voltage, and at least one switching timing parameter of the electronic switches.

3. The DC/DC switching converter of claim 2, further comprising:
a third circuit configured to directly measure the input current or the output current of the switching converter,
wherein determining the indirect current measurement comprises determining the indirect current measurement based, at least in part, on the output voltage measured by the first circuit, the input voltage measured by the second circuit, and the direct measurement of the input or the output current measured by the fourth circuit.

4. The DC/DC switching converter of claim 2, further comprising:
a fourth circuit configured to measure the at least one switching timing parameter, wherein the third circuit comprises:
an amplitude normalization circuit configured to normalize an analog voltage pulse waveform received as input;
a low pass filter coupled to the output of the amplitude normalization circuit and configured to filter the normalized analog voltage pulse waveform to produce a DC voltage proportional to a pulse width of at least one pulse in the normalized analog voltage pulse waveform, wherein a representation of the DC voltage is provided to the controller as the at least one switching timing parameter.

5. The DC/DC switching converter of claim 4, wherein the low pass filter further comprises:
a calibrated current source; and
a calibrated capacitor, wherein the low pass filter is configured to produce the DC voltage by charging the calibrated capacitor using the calibrated current source for a number of fixed time intervals corresponding to the pulse width of the at least one pulse in the normalized analog voltage pulse waveform.

6. The DC/DC switching converter of claim 4, wherein the fourth circuit further comprises:
a multiplexer configured to multiplex the output voltage from the first circuit, the input voltage from the second circuit, and the DC voltage from the fourth circuit; and
an analog to digital converter (ADC) configured to receive the output of the multiplexer, convert the multiplexed output into digital signals, and provide the digital signals to the controller.

7. The DC/DC switching converter of claim 2, wherein the controller is further configured to determine the efficiency of the switching converter as a ratio of a theoretical duty ratio of the switching converter and a measured duty ratio of the switching converter.

8. The DC/DC switching converter of claim 1, wherein the switching converter is configured as a buck switching converter, and wherein the indirect current measurement is a measurement of the output current of the buck switching converter.

9. The DC/DC switching converter of claim 1, wherein the switching converter is configured as a boost switching converter, and wherein the indirect current measurement is a measurement of the input current of the boost switching converter.

10. The DC/DC switching converter of claim 1, wherein the switching converter is selected from the group consisting of a buck converter, a boost converter, a buck-boost converter, and a SEPIC converter.

11. The DC/DC switching converter of claim 1, wherein the at least one switching parameter comprises a switching on time and a switching period.

12. A method of indirectly determining an input current or an output current of a DC/DC switching converter operating in a closed loop, the method comprising:
determining, by a controller, an efficiency of the switching converter based, at least in part, on an input voltage of the switching converter, an output voltage of the switching converter, and at least one switching timing parameter for controlling electronic switches in the switching converter;
directly measuring the input current or the output current of the switching converter using a current sensor; and
indirectly determining by the controller the input current or the output current, whichever is not directly determined by the current sensor, wherein the indirectly determining is based, at least in part, on the efficiency of the switching converter and the directly determined input current or output current.

13. The method of claim 12, further comprising:
determining the at least one switching timing parameter based, at least in part, on an analysis of an analog voltage pulse waveform.

14. The method of claim 13, wherein determining the at least one switching timing parameter comprises:
normalizing the analog voltage pulse waveform to a reference voltage such that when an amplitude of the analog voltage pulse waveform is equal to the reference voltage the analog voltage pulse waveform is associated with a 100% duty ratio.

15. The method of claim 14, wherein determining the at least one switching timing parameter further comprises:
filtering the normalized analog voltage pulse waveform with a low pass filter to convert the normalized analog voltage pulse waveform into a DC voltage proportional to a pulse width of at least one pulse in the normalized analog voltage pulse waveform;
converting the DC voltage into a digital signal, and wherein the method further comprises providing the digital signal to the controller as the at least one switching timing parameter.

16. The method of claim 15, wherein filtering the normalized analog voltage pulse waveform comprises:
charging a calibrated capacitor for a number of fixed time intervals corresponding to the pulse width of the at least one pulse in the normalized analog voltage pulse waveform;
counting the number of fixed time intervals during which the calibrate capacitor is charging; and
producing the DC voltage based on the counted number of fixed time intervals.

17. A wireless power receiver for a wireless charging system, the wireless power receiver comprising:
a DC/DC switching converter configured to indirectly determine an output current or an input current of the switching converter based, at least in part, on an efficiency of the switching converter.

18. The wireless power receiver of claim 17, wherein the DC/DC switching converter is further configured to determine the efficiency of the switching converter based, at least in part, on an input voltage of the switching converter, an output voltage of the switching converter, and at least one switching timing parameter of electronic switches in the switching converter.

19. The wireless power receiver of claim 18, wherein the DC/DC switching converter is further configured to directly measure the input or the output current of the switching converter, and wherein indirectly determining the output current or the input current comprises indirectly determining the output current or the input current based, at least in part, on the output voltage of the switching converter, the input voltage of the switching converter, and the direct measurement of the input current or the output current.

20. The wireless power receiver of claim 18, wherein the at least one switching timing parameter comprises a switching converter duty factor, and wherein the DC/DC switching converter is further configured to directly measure the input current of the switching converter and indirectly determine the output current, wherein indirectly determining the output current comprises determining the output current based, at least in part, on the output voltage of the switching converter, the input voltage of the switching converter, and the switching converter duty factor.

21. The wireless power receiver of claim 20, wherein the DC/DC switching converter is further configured to change an output impedance of the switching converter based, at least in part, on the efficiency of the switching converter.

22. The wireless power receiver of claim 21, wherein changing the output impedance of the switching converter comprises determining whether the efficiency of the switching converter is lower than a predetermined value and regulating the output impedance when it is determined that the efficiency of the switching converter is lower than the predetermined value.

23. The wireless power receiver of claim 21, wherein changing the output impedance of the switching converter comprises changing the output impedance based, at least in part, on at least one control signal received via an in-band or out-of-band communication or on a receiver or switching converter environmental input.

24. The wireless power receiver of claim 23, wherein the environmental input is a temperature inside the wireless power receiver.
